(19) United States
(12) Patent Application Publication
(10) Pub. No.: US 2019/0123887 A1
(43) Pub. Date: Apr. 25, 2019

(54) SIMULTANEOUS BIDIRECTIONAL FULL DUPLEX LINK

(71) Applicant: QUALCOMM Incorporated, San Diego, CA (US)

(72) Inventor: Bo Sun, Carlsbad, CA (US)

(21) Appl. No.: 15/788,615

(22) Filed: Oct. 19, 2017

(51) Int. Cl. H04L 5/14; H03H 7/40

(52) U.S. Cl. CPC H04L 5/1461; H03H 7/40; H04L 5/1423

(57) ABSTRACT

In certain aspects of the present disclosure, a chip includes a signal driver having an output coupled to a terminal of a bidirectional link, wherein the signal driver is configured to transmit a first signal to another chip via the bidirectional link. The chip also includes a replica driver configured to generate a replica echo signal, a receiver having a first input coupled to the terminal of the bidirectional link and a second input coupled to the replica driver, and a tunable load coupled between the replica driver and the second input of the receiver. The receiver is configured to receive a second signal at the first input, to receive the replica echo signal at the second input, and to subtract the replica echo signal from the second signal.

### BACKGROUND

### Field

Aspects of the present disclosure relate generally to bidirectional links, and more particularly, to bidirectional links with echo cancellation.

### Background

An electronic device (e.g., mobile wireless device) may include multiple chips (dies). The multiple chips may be packaged together (e.g., in a multi-chip module (MCM)), and may communicate with one another via chip-to-chip links.

### SUMMARY

The following presents a simplified summary of one or more embodiments in order to provide a basic understanding of such embodiments. This summary is not an extensive overview of all contemplated embodiments, and is intended to neither identify key or critical elements of all embodiments nor delineate the scope of any or all embodiments. Its sole purpose is to present some concepts of one or more embodiments in a simplified form as a prelude to the more detailed description that is presented later.

A first aspect relates to a chip. The chip includes a signal driver having an output coupled to a terminal of a bidirectional link, wherein the signal driver is configured to transmit a first signal to another chip via the bidirectional link. The chip also includes a replica driver configured to generate a replica echo signal, a receiver having a first input coupled to the terminal of the bidirectional link and a second input coupled to the replica driver, and a tunable load coupled between the replica driver and the second input of the receiver. The receiver is configured to receive a second signal at the first input, to receive the replica echo signal at the second input, and to subtract the replica echo signal from the second signal.

A second aspect relates to a system. The system includes a first chip, a second chip, and a bidirectional link coupled between the first chip and the second chip. The first chip includes a first signal driver configured to transmit a first signal to the second chip via the bidirectional link, and a replica driver configured to generate a replica echo signal. The second chip includes a second signal driver configured to transmit a second signal to the first chip via the bidirectional link. The first chip further includes a receiver having a first input and a second input, and a tunable load coupled between the replica driver and the second input of the receiver. The receiver is configured to receive a combined signal at the first input, the combined signal comprising the second signal and an echo signal of the first signal driver, to receive the replica echo signal at the second input, and to subtract the replica echo signal from the combined signal.

To the accomplishment of the foregoing and related ends, the one or more embodiments include the features hereinafter fully described and particularly pointed out in the claims. The following description and the annexed drawings set forth in detail certain illustrative aspects of the one or more embodiments. These aspects are indicative, however, of but a few of the various ways in which the principles of various embodiments may be employed and the described embodiments are intended to include all such aspects and their equivalents.

### BRIEF DESCRIPTION OF THE DRAWINGS

FIG. 1 shows an example of two chips that communicate with one another via unidirectional links.

FIG. 2 shows an example of two chips that communicate with one another via a bidirectional link according to certain aspects of the present disclosure.

FIG. 3 shows an example of tunable loads for providing improved echo cancellation according to certain aspects of the present disclosure.

FIG. 4 shows an exemplary implementation of a tunable load comprising a lumped RLC circuit according to certain aspects of the present disclosure.

FIG. 5 shows an exemplary implementation of the lumped RLC comprising multiple switchable segments according to certain aspects of the present disclosure.

FIG. 6 shows an example of controllers configured to operate a bidirectional link in a bidirectional mode or a unidirectional mode according to certain aspects of the present disclosure.

FIG. 7 shows an example of two chips that communicate with one another via a bidirectional link in which one of the chips includes a baseband modem and the other chip includes an RF transceiver according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

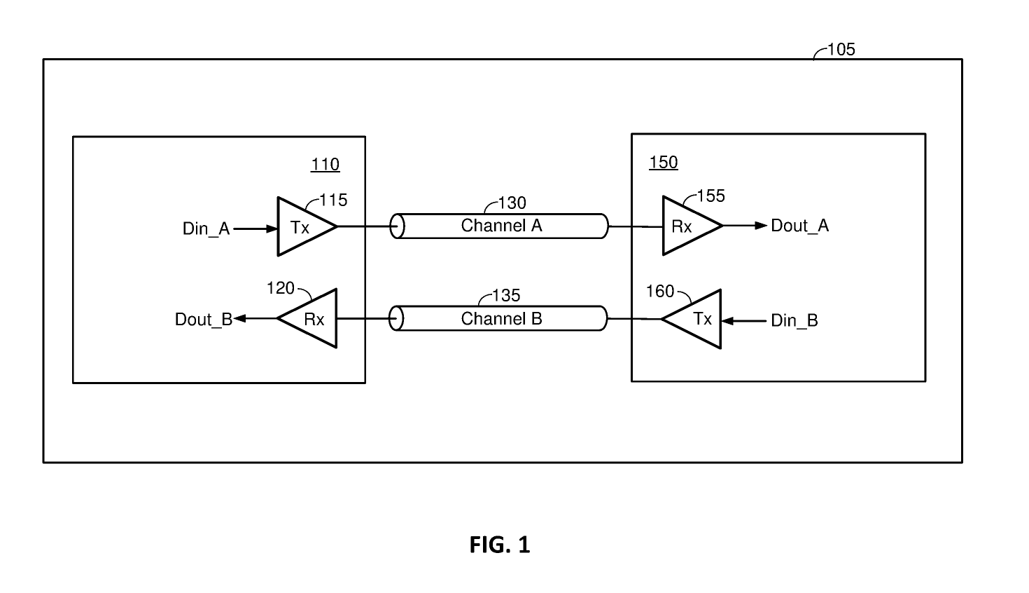

An electronic device may include multiple chips (dies) that communicate with one another. In this regard, FIG. 1 shows an example of a first chip 110 and a second chip 150 that communicate with one another via a first unidirectional link 130 and a second unidirectional link 135. The first and second chips 110 and 150 may be mounted on a substrate 105 (e.g., a printed circuit board (PCB), a ceramic substrate, or another type of substrate). Each link (also referred to as a channel) may include one or more pins, one or more conductive traces on the substrate 105, a cable, one or more wires, or any combination thereof.

In this example, the first chip 110 includes a signal driver 115 (also referred to as a transmitter) for transmitting signals to the second chip 150 via the first unidirectional link 130, and the second chip 150 includes a signal driver 160 for transmitting signals to the first chip 110 via the second unidirectional link 135. The first chip 110 also includes a receiver 120 for receiving signals from the second chip 150 via the second unidirectional link 135, and the second chip 150 includes a receiver 155 for receiving signals from the first chip 110 via the first unidirectional link 130. Thus, in this example, the first unidirectional link 130 is used for transporting signals from the first chip 110 to the second chip 150, and the second unidirectional link 135 is used for transporting signals from the second chip 150 to the first chip 110.

A drawback of the chip-to-chip interface shown in FIG. 1 is that it requires at least two unidirectional links 130 and 135 to support communication between the first and second chips 110 and 150 in both directions. The need for at least two unidirectional links may lead to routing congestion between the chips 110 and 150, especially as more links are needed to support higher bandwidths (e.g., for the new 5th generation (5G) standard).

To overcome the above drawback of unidirectional links, a bidirectional link may be used to provide communication between two chips in both directions.

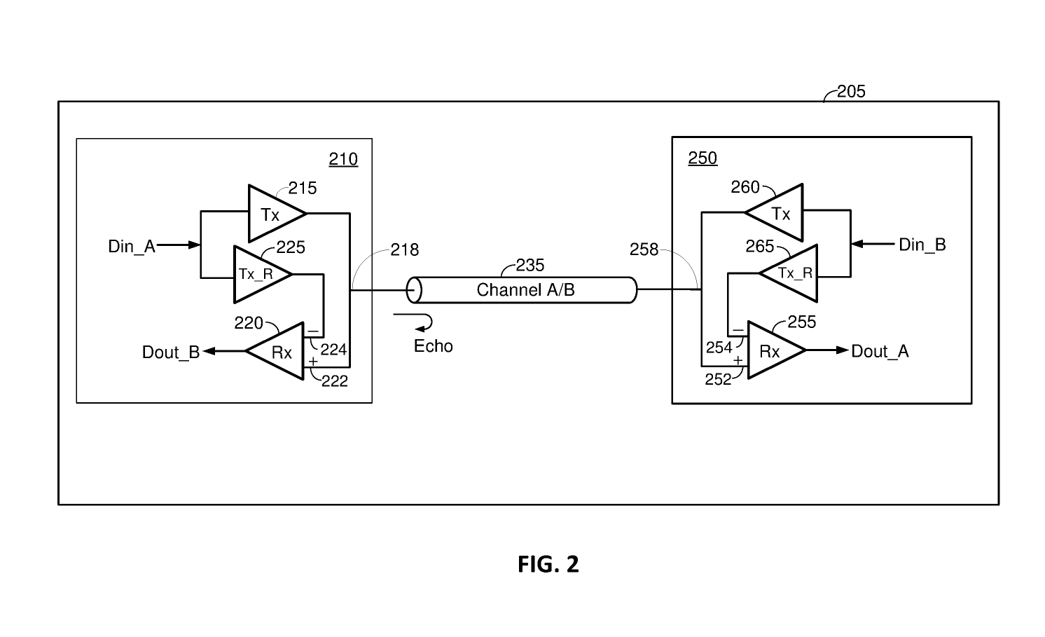

In this regard, FIG. 2 shows an example of a first chip 210 and a second chip 250 that communicate with each other via a bidirectional link 235 (also referred to as a bidirectional channel) in both directions. The first and second chips 210 and 250 may be mounted on a substrate 205 (e.g., PCB, a ceramic substrate, or another type of substrate). The bidirectional link 235 may include one or more pins, one or more conductive traces on the substrate 205, a cable, one or more wires, or any combination thereof.

The first chip 210 includes a signal driver 215 (also referred to as a transmitter). The output of the signal driver 215 is coupled to a first terminal 218 of the bidirectional link 235. The signal driver 215 is configured to receive a signal (labeled “Din_A”) and output the received signal to the first terminal 218 of the bidirectional link 235 for transmission to the second chip 250 via the bidirectional link 235. The signal Din_A may come from a processor (not shown) on the first chip 210. The second chip 250 includes a signal driver 260. The output of the signal driver 260 is coupled to a second terminal 258 of the bidirectional link 235. The signal driver 260 is configured to receive a signal (labeled “Din_B”) and output the received signal to the second terminal of 258 of the bidirectional link 235 for transmission to the first chip 210 via the bidirectional link 235. The signal Din_B may come from a processor (not shown) on the second chip 250.

The first chip 210 also includes a receiver 220 configured to receive a signal from the signal driver 260 on the second chip 250 via the bidirectional link 235, and output the received signal (labeled “Dout_B”). For example, the receiver 220 may output the received signal Dout_B to a processor (not shown) on the first chip 210 for further processing. The second chip 250 includes a receiver 255 configured to receive a signal from the signal driver 215 on first chip 210 via the bidirectional link 235, and output the received signal (labeled “Dout_A”). For example, the receiver 255 may output the received signal Dout_A to a processor (not shown) on the second chip 250 for further processing. Thus, the first chip 210 and the second chip 250 are able to communicate with each other in both directions via the bidirectional link 235.

The bidirectional link 235 supports simultaneous communication between the first and second chips 210 and 250 in both directions. As a result, the bandwidth (throughput) of the bidirectional link 235 is effectively double the bandwidth (throughput) of a single unidirectional link. This reduces the number of links needed to support higher bandwidths. The reduction in the number of links reduces routing congestion between the chips 210 and 250, and saves area on the substrate 205 (e.g., PCB).

However, the use of the bidirectional link 235 requires echo cancellation. This can be explained with reference to FIG. 2. Ideally, a signal output by the signal driver 215 on the first chip 210 is transported to the receiver 255 on the second chip 250 via the bidirectional link 235, and a signal output by the signal driver 260 on the second chip 250 is transported to the receiver 220 on the first chip 210 via the bidirectional link 235. However, a portion of the signal output by the signal driver 215 on the first chip 210 is reflected back to the receiver 220 on the first chip 210 as an echo signal. Thus, the receiver 220 on the first chip 210 receives the echo signal in addition to the intended signal from the signal driver 260 on the second chip 250.

To cancel out the echo signal at the receiver 220, the first chip 210 includes a replica driver 225 that receives the same input signal as the signal driver 215, and generates a replica echo signal. The receiver 220 has a first input 222 coupled to the first terminal 218 of the bidirectional link 235, and a second input 224 coupled to the output of the replica driver 225. The receiver 220 is configured to receive the combined echo signal and the intended signal at the first input 222, and receive the replica echo signal at the second input 224. The receiver 220 subtracts the replica echo signal at the second input 224 from the combined echo signal and intended signal at the first input 222. If the replica echo signal perfectly matches the echo signal, then the echo signal is canceled out, leaving only the intended signal at the output of the receiver 220.

Perfect echo cancellation requires that an output load impedance of the replica driver 225 perfectly match the impedance characteristics of the bidirectional link 235 among other requirements. However, in practice, it is difficult to match the load impedance of the replica driver 225 with the characteristic impedance of the bidirectional link 235. This is because the characteristic impedance of the bidirectional link 235 can vary from device to device (e.g., due to variations in manufacturing) and may not be accurately known. The resulting mismatch between the output load impedance of the replica driver 225 and the characteristic impedance of the bidirectional link 235 leads to imperfect echo cancellation at the first chip 210. As a result, a portion (residual) of the echo signal is output by the receiver 220, lowering the noise margin.

Echo cancellation is performed in a similar manner at the second chip 250 using a replica driver 265 on the second chip 250. More particularly, the replica driver 265 receives the same input signal as the signal driver 260, and generates a replica echo signal. The receiver 255 has a first input 252 coupled to the second terminal 258 of the bidirectional link 235, and a second input 254 coupled to the output of the replica driver 265. The receiver 255 is configured to receive a combined echo signal and intended signal at the first input 252, in which the echo signal is the echo signal of the signal driver 260 on the second chip 250 and the intended signal is a signal transmitted by the signal driver 215 on the first chip 210. The receiver 255 is also configured to receive the replica echo signal from the replica driver 265 at the second input 254. The receiver 255 subtracts the replica echo signal at the second input 254 from the combined echo signal and intended signal at the first input 252 to cancel out the echo signal. Similar to echo cancellation at the first chip 210, mismatch between the output load impedance of the replica driver 265 and the characteristic impedance of the bidirectional link 235 leads to imperfect echo cancellation at the second chip 250. As a result, a portion (residual) of the echo signal is output by the receiver 255, lowering the noise margin.

Embodiments of the present disclosure provide a tunable load coupled to the output of a replica driver, in which the impedance of the load can be tuned (adjusted) to closely match the characteristic impedance of the bidirectional link. The tuning range of the load may cover a range of characteristic impedances for the bidirectional link corresponding to different package designs, traces, cables, etc. By closely matching the characteristic impedance of the bidirectional link (bidirectional channel), the tunable load provides increased echo cancellation.

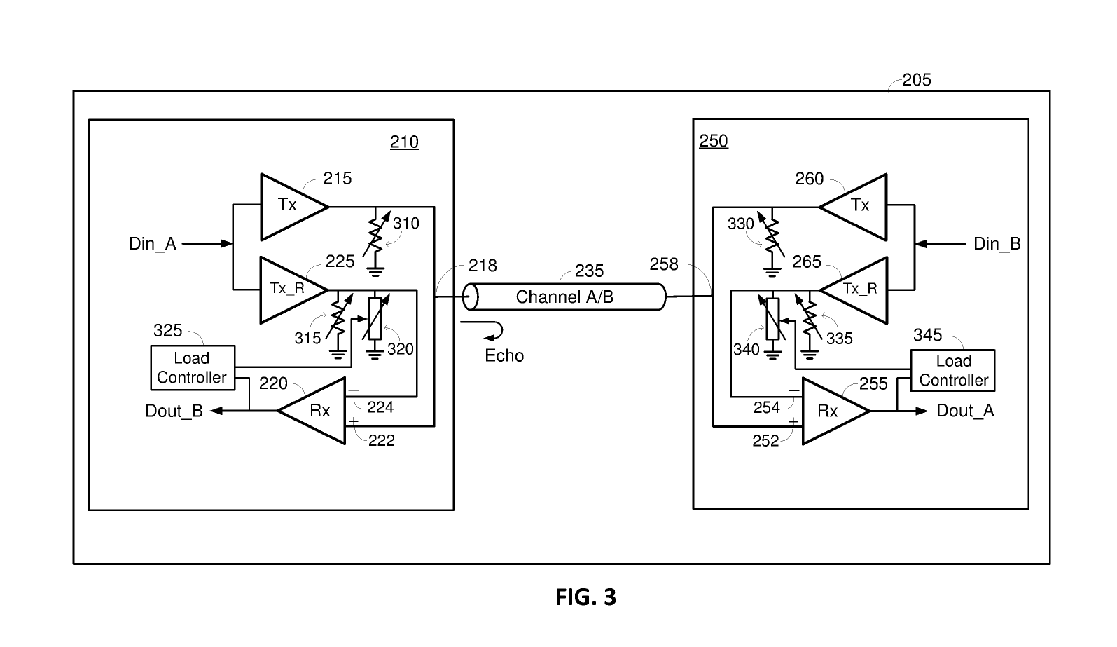

FIG. 3 shows an example in which each of the first and second chips 210 and 250 includes a tunable load for increasing echo cancellation, as discussed further below.

In the example shown in FIG. 3, the first chip 210 includes a termination load 310 coupled to the output of the signal driver 215, and a replica termination load 315 coupled to output of the replica driver 225. Each of the termination loads 310 and 315 may have a tunable resistance. In this example, the resistance of the termination load 310 may be tuned to reduce signal reflections at the boundary between the first chip 210 and the bidirectional link 235. The resistance of the replica terminal load 315 may be tuned to match the resistance of the termination load 310.

The first chip 210 also includes a tunable load 320 coupled to the output of the replica driver 225. The load 320 has a tunable impedance, which can be tuned to closely match the characteristic impedance of the bidirectional link 235 for increased echo cancellation. The increased echo cancellation decreases the portion (residual) of the echo signal output by the receiver 220, improving the noise margin. In certain embodiments, the tunable load 320 is implemented with a lumped resistor-inductor-capacitor (RLC) circuit, as discussed further below.

The first chip 210 may also include a load controller 325 configured to tune the impedance of the load 320. In one example, the load controller 325 may tune the impedance of the load 320 during a calibration procedure. During the calibration procedure, the signal driver 215 on the first chip 210 is driven with a signal while the signal driver 260 on the second chip 250 is disabled. Since the signal driver 260 on the second chip 250 is disabled, the signal strength at the output of the receiver 220 is due to the echo signal of the signal driver 215 on the first chip 210. In this example, the load controller 325 may tune (adjust) the impedance of the load 320 while sensing the signal strength at the output of the receiver 220, and record the impedance setting at which the signal strength at the output of the receiver 220 is approximately zero. This occurs when the impedance of the load 320 approximately matches the characteristic impedance of the bidirectional link 235. During normal operation, the load controller 325 sets the impedance of the load 320 according to the impedance setting determined during the calibration procedure. It is to be appreciated that the present disclosure is not limited to the exemplary calibration procedure discussed above, and that the impedance of the load 320 may be determined using other techniques.

In the example shown in FIG. 3, the second chip 250 includes a termination load 330 coupled to the output of the signal driver 260, and a replica termination load 335 coupled to output of the replica driver 265. Each of the termination loads 330 and 335 may have a tunable resistance, in which the resistance of the termination load 330 is tuned to reduce signal reflections at the boundary between the second chip 250 and the bidirectional link 235, and the resistance of the replica terminal load 335 is tuned to match the resistance of the termination load 330.

The second chip 250 also includes a tunable load 340 coupled to the output of the replica driver 265 for increasing echo cancellation, and may have a similar structure as the tunable load 320 on the first chip 210. The load 340 has a tunable impedance, which can be tuned to closely match the characteristic impedance of the bidirectional link 235 for increased echo cancellation. The increased echo cancellation decreases the portion (residual) of the echo signal output by the receiver 255, improving the noise margin. The tunable load 340 may be implemented with a lumped RLC circuit, as discussed further below.

The second chip 250 may also include a load controller 345 configured to tune the impedance of the load 340 to increase echo cancellation at the second chip 250. In one example, the load controller 345 may tune the impedance of the load 340 during a calibration procedure similar to the calibration procedure discussed above for the load 320 on the first chip 210. During the calibration procedure, the signal driver 260 on the second chip 250 is driven with a signal while the signal driver 215 on the first chip 210 is disabled. In this example, the load controller 345 may tune (adjust) the impedance of the load 340 while sensing the signal strength at the output of the receiver 255, and record the impedance setting at which the signal strength at the output of the receiver 255 is approximately zero. During normal operation, the load controller 345 sets the impedance of the load 340 according to the impedance setting determined during the calibration procedure. It is to be appreciated that the present disclosure is not limited to the exemplary calibration procedure discussed above, and that the impedance of the load 340 may be determined using other techniques.

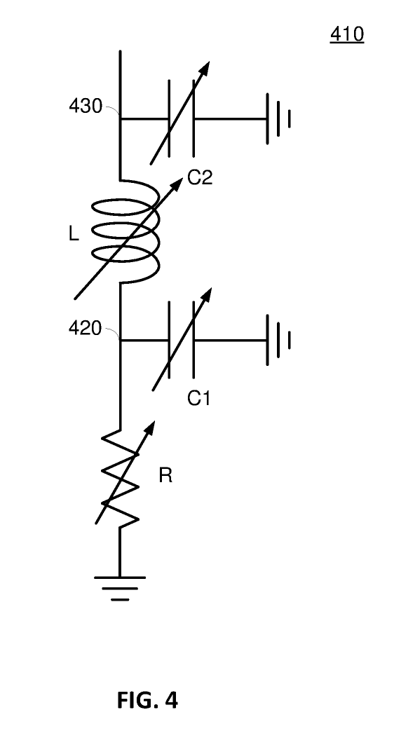

As discussed above, each one of the tunable loads 320 and 340 may be implemented with a lumped RLC circuit. In this regard, FIG. 4 shows an example of a tunable load 410 including a lumped RLC circuit according to certain aspects of the present disclosure. Each one of the tunable loads 320 and 340 may be implemented with the tunable load 410 shown in FIG. 4 (i.e., each one of the tunable loads 320 and 340 may comprise a duplicate of the tunable load 410 shown in FIG. 4).

The tunable load 410 includes an inductor L, a resistor R, a first capacitor C1, and a second capacitor C2. In the example shown in FIG. 4, the resistor R is coupled between a first end 420 of the inductor L and ground, the first capacitor C1 is coupled between the first end 420 of the inductor L and ground, and the second capacitor C2 is coupled between a second end 430 of the inductor L and ground. The second end 430 of the inductor L is coupled to the output of the respective replica driver. Thus, for the example in which the tunable load 410 implements the tunable load 320 on the first chip 210, the second end 430 of the inductor L is coupled to the output of the replica driver 225 on the first chip 210. For the example in which the tunable load 410 implements the tunable load 340 on the second chip 250, the second end 430 of the inductor L is coupled to the output of the replica driver 265 on the second chip 250.

The resistor R has a tunable resistance, the inductor L has a tunable inductance, and each one of the first and second capacitors C1 and C2 has a tunable capacitance. The resistance of the resistor R may be used to model a resistance of the bidirectional link 235, the inductor L may be used to model an inductance of the bidirectional link 235, and the capacitance of each of the first and second capacitors C1 and C2 may be used to model a capacitance of the bidirectional link 235. The impedance of the tunable load 410 is tuned (adjusted) by tuning the resistance of the resistor R, tuning the inductance of the inductor L, and/or tuning the capacitances of the capacitors C1 and C2. The inductor L may be continuously adjustable (i.e., the inductance of the inductor L may be continuously adjusted within a certain range). Alternatively, the inductor L may be discrete adjustable (i.e., the inductance of the inductor L may be set to any one of multiple discrete inductance values). Similarly, the resistor R may be continuously adjustable or discrete adjustable, and each one of the first and second capacitors C1 and C2 may be continuously adjustable or discrete adjustable.

For the example in which the tunable load 410 implements the tunable load 320 on the first chip 210, the load controller 325 may tune (adjust) the impedance of the load 320 by tuning the resistance of the resistor R, tuning the inductance of the inductor L, and/or tuning the capacitances of the capacitors C1 and C2. In this example, the load controller 325 may tune the impedance of the load 320 during calibration until the impedance of the load 320 closely matches the characteristic impedance of the bidirectional link 235, as discussed above. During normal operation, the load controller 325 may set the resistance of the resistor R, the inductance of the inductor L, and/or the capacitances of the capacitors C1 and C2 according to the resistance setting, the inductance setting, and/or the capacitance settings determined during calibration.

For the example in which the tunable load 410 implements the tunable load 340 on the second chip 250, the load controller 345 may tune (adjust) the impedance of the load 340 by tuning the resistance of the resistor R, tuning the inductance of the inductor L, and/or tuning the capacitances of the capacitors C1 and C2. In this example, the load controller 345 may the tune the impedance of the load 340 during calibration until the impedance of the load 340 closely matches the characteristic impedance of the bidirectional link 235, as discussed above. During normal operation, the load controller 345 may set the resistance of the resistor R, the inductance of the inductor L, and/or the capacitances of the capacitors C1 and C2 according to the resistance setting, the inductance setting, and/or the capacitance settings determined during calibration.

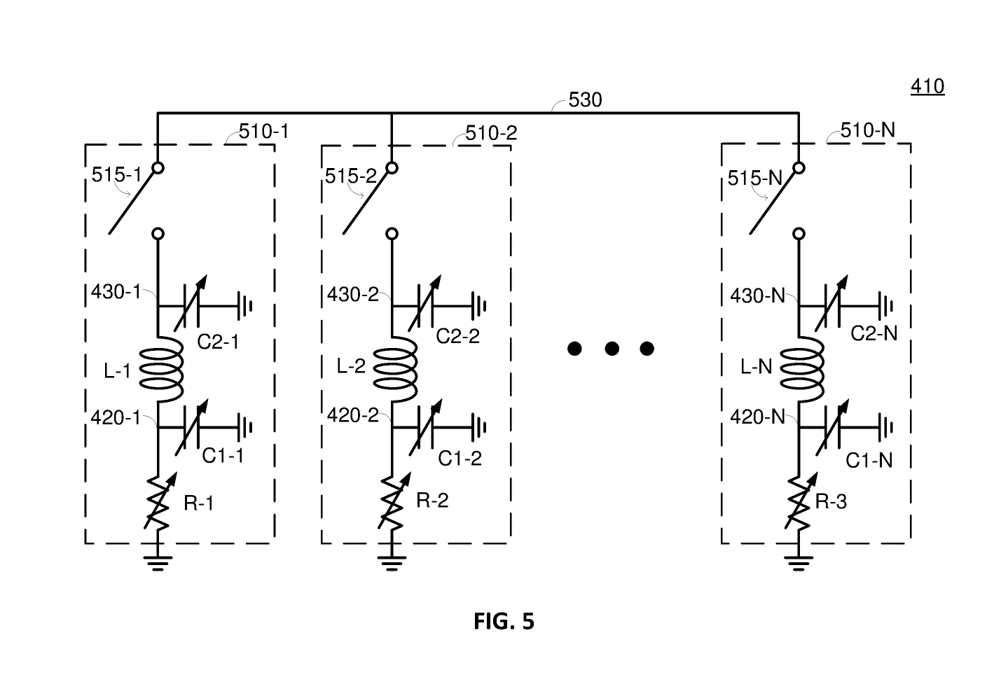

FIG. 5 shows an exemplary implementation of the tunable load 410 according to certain aspects of the present disclosure. In this example, the tunable load 410 includes multiple segments 510-1 to 510-N, in which each segment 510-1 to 510-n includes a respective lumped RLC circuit that models the characteristic impedance of the bidirectional link 235. The lumped RLC circuit in each segment 510-1 to 510-N includes a respective inductor L-1 to L-N, a respective resistor R-1 to R-N, and respective first and second capacitors C1-1 to C1-N and C2-1 to C2-N. In each segment 510-1 to 510-N, the respective resistor R-1 to R-N is coupled between a first end 420-1 to 420-N of the respective inductor L-1 to L-N and ground, the respective first capacitor C1-1 to C1-N is coupled between the first end 420-1 to 420-N of respective the inductor L-1 to L-N and ground, and the second capacitor C2-1 to C2-N is coupled between a second end 430-1 to 430-N of the respective inductor L-1 to L-N and ground.

Each segment 510-1 to 510-N also includes a respective switch 515-1 to 515-N that controls whether the segment is coupled to the output of the respective replica driver (not shown in FIG. 5) through line 530. In the example shown in FIG. 5, the switch 515-1 to 515-N in each segment 510-1 to 510-N is coupled between the second end 430-1 to 430-N of the respective inductor L-1 to L-N and the output of the respective replica driver.

In some aspects, the inductor L-1 to L-N in each segment has a fixed inductance. In these aspects, the inductor L-1 to L-N in each segment may be implemented with a planar spiral inductor integrated on the respective chip, or another type of integrated inductor.

The inductor L-1 to L-N in each segment may have a different inductance. In this example, the inductance of the load 410 may be set to the inductance of the any one of the inductors L-1 to L-N by coupling the respective segment to line 530, which is coupled to the output of the respective replica driver. This is accomplished by closing the switch of the respective segment, and opening the switches of the other segments. For example, the inductance of the load 410 may be set to the inductance of the inductor L-1 in segment 510-1 by closing switch 515-1 and opening switches 510-2 to 510-N.

In operation, the impedance of the load 410 may be tuned (e.g., by the respective one of the load controller 325 and 345) as follows. The inductance of the load 410 may be tuned by selectively coupling one of the segments 510-1 to 510-N to the respective replica driver at a time. A particular one of the segment is selected by closing the respective switch and opening the other switches. In this example, the inductance of the load 410 corresponds to the inductance of the inductor in the currently selected segment. The resistance of the load 410 may be tuned by tuning the resistance of the resistor in the currently selected segment, and the capacitances of the load 410 may be tuned by tuning the capacitances of the first and second capacitors in the currently selected segment.

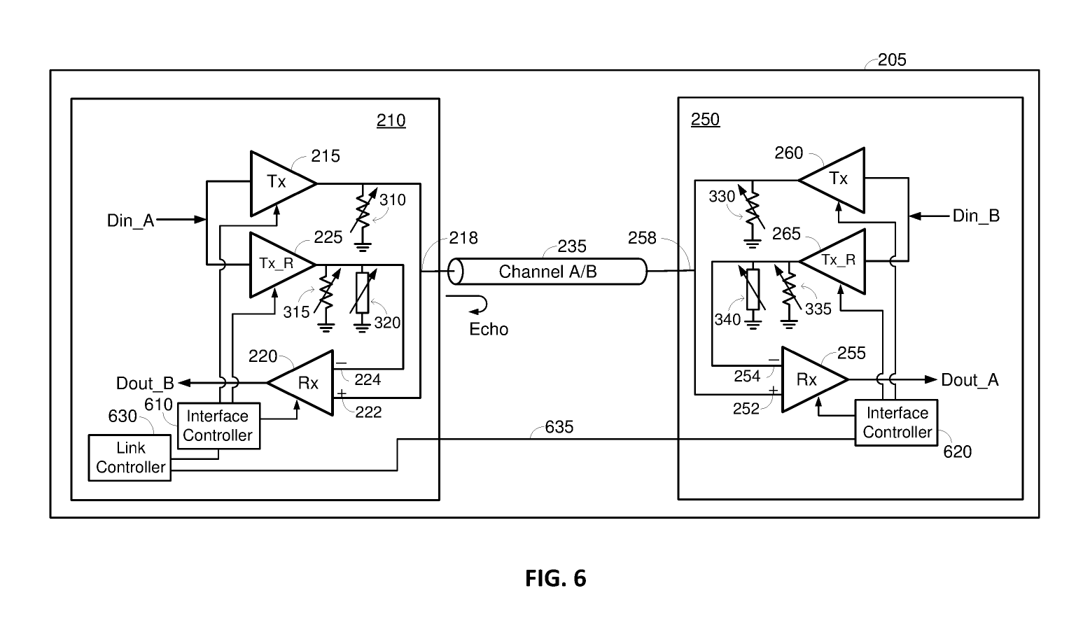

In certain aspects, the bidirectional link 235 may be operated in a unidirectional mode, in which signals are transmitted across the link 235 in one direction at a time. For example, the bidirectional link 235 may be operated in the unidirectional mode for applications that do not require high bandwidth (throughput) in both directions and/or to provide backwards compatibility for systems that use unidirectional communication on one link, as discussed further below. FIG. 6 shows an example in which the first chip 210 includes a first interface controller 610, and the second chip 250 includes a second interface controller 620. The interface controllers 610 and 620 are configured to operate the link 235 in the unidirectional mode discussed above, or a simultaneous bidirectional mode.

In the bidirectional mode, the first interface controller 610 enables the signal driver 215, the replica driver 225, and the receiver 220 on the first chip 210, and the second interface controller 620 enables the signal driver 260, the replica driver 265, and the receiver 255 on the second chip 250. In this mode, signals may be transmitted between the first and second chips 210 and 250 simultaneously in both directions, as discussed above. More particularly, the signal driver 215 on the first chip 210 transmits signals to the receiver 255 on the second chip 250 via the link 235 in one direction, and the signal driver 260 on the second chip 250 transmits signals to the receiver 220 on the first chip 210 via the link 235 in the opposite direction. The replica driver 225 and the tunable load 320 are used to provide echo cancellation at the first chip 210, and the replica driver 255 and the tunable load 340 are used to provide echo cancellation at the second chip 250, as discussed above. The interface controllers 610 and 620 may operate the link 235 in the bidirectional mode, for example, for applications requiring high bandwidth in both directions.

In the unidirectional mode, the first and second interface controllers 610 and 620 enable communication across the link 235 in one direction at a time. For example, for communication from the first chip 210 to the second chip 250, the first interface controller 610 enables the signal driver 215 on the first chip 210, and disables the replica driver 225 and the receiver 220 on the first chip 210. The replica driver 225 and the receiver 220 are disabled since they are not needed for communication from the first chip 210 to the second chip 250. The second interface controller 620 enables the receiver 255 on the second chip 250, and disables the replica driver 255 and the signal driver 260 on the second chip 250. The replica driver 255 and the signal driver 260 are disabled since they are not needed for communication from the first chip 210 to the second chip 250. In operation, the signal driver 215 on the first chip 210 transmits signals to the receiver 255 on the second chip 250 via the link 235.

For communication from the second chip 250 to the first chip 210, the first interface controller 610 enables the receiver 220 on the first chip 210, and disables the replica driver 225 and the signal driver 215 on the first chip 210. The second interface controller 620 enables the signal driver 260 on the second chip 250, and disables the replica driver 265 and the receiver 255 on the second chip 250. In operation, the signal driver 260 on the second chip 250 transmits signals to the receiver 220 on the first chip 210 via the link 235.

In certain aspects, the first chip 210 may include a link controller 630 configured to control the first and second interface controllers 610 and 620 to operate the link 235 in the bidirectional mode or the unidirectional mode. The link controller 630 may communicate with the second interface controller 620 on the second chip 250 via a control link 635. Although not shown in FIG. 6, it is to be understood that the first chip 210 may include a driver for transmitting control signals on the control link 635, and the second chip 250 may include a receiver for receiving the control signals on the control link 635.

In operation, the link controller 630 may receive a signal indicating whether the first and second chips 210 and 250 are to operate in the bidirectional mode or the unidirectional mode. If the signal indicates the bidirectional mode, then the link controller 630 commands the first and second interface controllers 610 and 620 to operate in the bidirectional mode. In this case, the first interface controller 610 enables the receiver 220, the replica driver 225, and the signal driver 215 on the first chip 210, and the second interface controller 620 enables the signal driver 260, the replica driver 265, and the receiver 255 on the second chip 250, as discussed above.

If the signal indicates the unidirectional mode, then the signal may also indicate the direction of the unidirectional communication. For example, if the signal indicates the unidirectional mode and the direction from the first chip 210 to the second chip 250, then the link controller 630 may send control signals to the interface controllers 610 and 620 to enable unidirectional communication from the first chip 210 to the second chip 250. In this case, the first interface controller 610 enables the signal driver 215 on the first chip 210, and disables the replica driver 225, and the receiver 220 on the first chip 210, and the second interface controller 620 enables the receiver 255 on the second chip 250, and disables the replica driver 265, and the signal driver 260 on the second chip 250.

If the signal indicates the unidirectional mode and the direction from the second chip 250 to the first chip 210, then the link controller 630 may send control signals to the interface controllers 610 and 620 to enable unidirectional communication from the second chip 250 to the first chip 210. In this case, the first interface controller 610 enables the receiver 220 on the first chip 210, and disables the replica driver 225, and the signal driver 215 on the first chip 210, and the second interface controller 620 enables the signal driver 260 on the second chip 250, and disables the replica driver 265, and the receiver 255 on the second chip 250, as discussed above.

As discussed above, the first interface controller 610 may enable or disable the replica driver 225 based on whether the link 235 is to be operated in the bidirectional mode or the unidirectional mode. In one example, the first interface controller 610 may enable or disable the replica driver 225 by selectively gating power to the replica driver 225 using a power switch (not shown) coupled between a power supply and the replica driver 225. In this example, the first interface controller 610 enables the replica driver 225 by turning on the power switch and disables the replica driver 225 by turning off the power switch. The first controller 610 may enable or disable the signal driver 215, and enable or disable the receiver 220 in a similar manner

Similarly, the second interface controller 620 may enable or disable the replica driver 265 by selectively gating power to the replica driver 265 using a power switch (not shown) coupled between a power supply and the replica driver 265. In this example, the second interface controller 620 enables the replica driver 265 by turning on the power switch and disables the replica driver 265 by turning off the power switch. The second controller 620 may enable or disable the signal driver 260, and enable or disable the receiver 255 in a similar manner

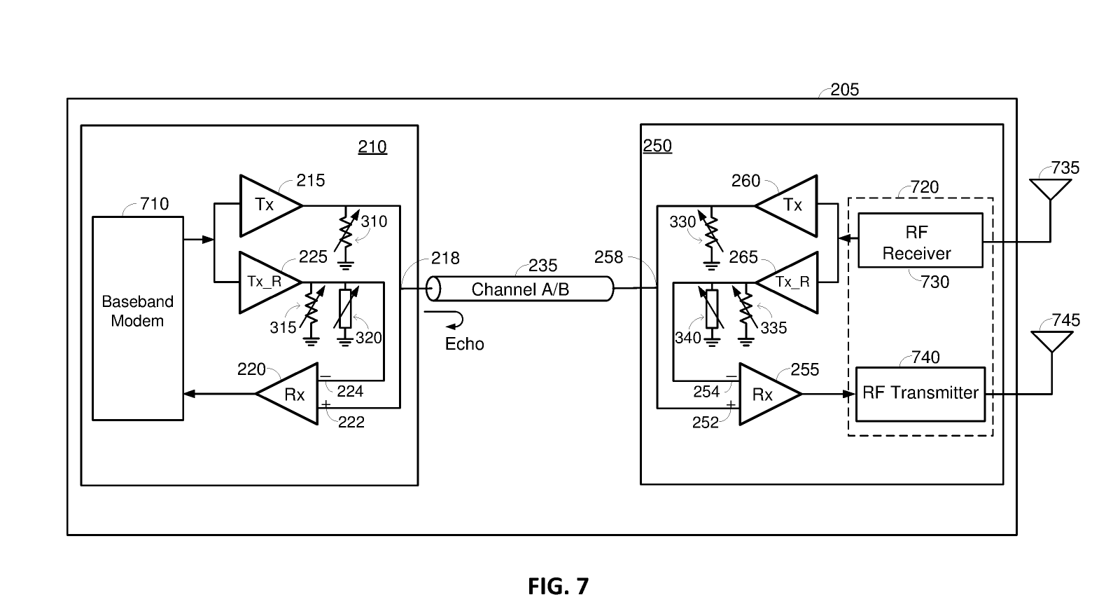

In certain aspects, the first chip 110 and the second chip 150 may be incorporated in a wireless device (e.g., mobile wireless device). In these aspects, the first chip 210 may include a baseband modem (also referred to as a baseband processor) and the second chip 250 may include a radio frequency (RF) transceiver. In this regard, FIG. 7 shows an example in which the first chip 210 includes a baseband modem 710, and the second chip 250 includes an RF transceiver 720. The RF transceiver 720 includes an RF receiver 730 configured to receive RF signals via one or more antennas 735, and an RF transmitter 740 configured to transmit RF signals via one or more antennas 745. Although FIG. 7 shows an example in which the RF receiver 730 and the RF transmitter 740 are coupled to different antennas, it is to be appreciated that the RF receiver 730 and the RF transmitter 740 may be coupled to one or more common antennas.

In operation, the baseband modem 710 generates a baseband signal for transmission. For example, the baseband modem 710 may modulate the baseband signal with data according to a modulation scheme (e.g., BPSK, QPSK, 16 QAM, 64 QAM, 64 APSK, 128 APSK, 256 QAM, 256 APSK, etc.). The data may come from a processor (not shown) on the first chip 210. The baseband modem 710 may output the baseband signal to the signal driver 215. The signal driver 215 transmits the baseband signal to the receiver 255 on the second chip 250 via the link 235. The receiver 255 receives the baseband signal from the link 235, and outputs the received baseband signal to the RF transmitter 740. The RF transmitter 740 may frequency up-convert the baseband signal into an RF signal, amplify the RF signal, and/or perform other operations. The RF transmitter 740 outputs the RF signal to the one or more antennas 745 for wireless transmission to another wireless device.

In the other direction, the RF receiver 730 receives an RF signal from another wireless device via the one or more antennas 735. The RF receiver 730 may amplify the received RF signal and frequency down-convert the received RF signal into a baseband signal. The RF receiver 730 may output the baseband signal to the signal driver 260. The signal driver 260 transmits the baseband signal to the receiver 220 on the first chip 210 via the link 235. The receiver 220 receives the baseband signal from the link 235, and outputs the received baseband signal to the baseband modem 710. The baseband modem 710 may demodulate the baseband signal to recover data from the baseband signal, and send the data to a processor (not shown) for further processing.

Within the present disclosure, it is to be understood that the bidirectional mode does not require simultaneous transmission in both directions all of the time, only that transmission in one direction overlaps transmission in the other direction in time. For example, it is to be appreciated that a transmission in one direction may finish before a transmission in the other direction is finished. Also, it is to be appreciated that transmissions in the two directions may be asynchronous with each other in time, and/or have different data rates.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two components.

The controllers 325, 345, 610, 620 and 630 discussed above may be implemented with a general-purpose processor, a digital signal processor (DSP), an application specific integrated circuit (ASIC), a field programmable gate array (FPGA) or other programmable logic device, discrete hardware components (e.g., logic gates), or any combination thereof designed to perform the functions described herein. A processor may perform the functions described herein by executing software comprising code for performing the functions. The software may be stored on a computer-readable storage medium, such as a RAM, a ROM, an EEPROM, an optical disk, and/or a magnetic disk.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a signal driver having an output coupled to a terminal of a bidirectional link, wherein the signal driver is configured to transmit a first signal to another chip via the bidirectional link;
a replica driver configured to generate a replica echo signal;
a receiver having a first input coupled to the terminal of the bidirectional link and a second input coupled to the replica driver, wherein the receiver is configured to:
receive a second signal at the first input;
receive the replica echo signal at the second input; and
subtract the replica echo signal from the second signal; and
a tunable load coupled between the replica driver and the second input of the receiver.

2. The chip of claim 1, wherein the second signal comprises a third signal received from the other chip via the bidirectional link and an echo signal of the signal driver.

3. The chip of claim 1, wherein the tunable load comprises a lumped resistor-inductor-capacitor (RLC) circuit.

4. The chip of claim 3, wherein the lumped RLC circuit comprises a plurality of segments, wherein each of the segments comprises:
a respective inductor; and
a respective switch coupled between the respective inductor and the replica driver.

5. The chip of claim 4, wherein the inductor of each of the segments has a different inductance.

6. The chip of claim 5, wherein the inductance of the inductor of each of the segments is fixed.

7. The chip of claim 4, wherein each of the segments further comprises:
a respective resistor coupled between a first end of the respective inductor and a ground;
a first capacitor coupled between the first end of the respective inductor and the ground; and
a second capacitor coupled between a second end of the respective inductor and the ground.

8. The chip of claim 1, further comprising an interface controller configured to:
enable the signal driver, the replica driver, and the receiver in a bidirectional mode; and
disable the replica driver in a unidirectional mode.

9. The chip of claim 8, wherein the interface controller is further configured to:
disable the receiver in the unidirectional mode for unidirectional communication from the chip to the other chip via the link; and
disable the signal driver in the unidirectional mode for unidirectional communication from the other chip to the chip via the link.

10. The chip of claim 1, further comprising a baseband modem configured to:
generate a first baseband signal; and
output the first baseband signal to the signal driver, wherein the first signal transmitted by the signal driver comprises the first baseband signal.

11. The chip of claim 10, wherein the second signal comprises a second baseband signal, and the receiver has an output coupled to the baseband modem.

12. A system, comprising:
a first chip;
a second chip; and
a bidirectional link coupled between the first chip and the second chip;
wherein the first chip comprises:
a first signal driver configured to transmit a first signal to the second chip via the bidirectional link; and
a replica driver configured to generate a replica echo signal;
wherein the second chip comprises a second signal driver configured to transmit a second signal to the first chip via the bidirectional link; and
wherein the first chip further comprises:
a receiver having a first input and a second input, wherein the receiver is configured to:
receive a combined signal at the first input, the combined signal comprising the second signal and an echo signal of the first signal driver;
receive the replica echo signal at the second input; and
subtract the replica echo signal from the combined signal; and
a tunable load coupled between the replica driver and the second input of the receiver.

13. The system of claim 12, further comprising a substrate, wherein the first chip and the second chip are mounted on the substrate.

14. The system of claim 12, wherein the tunable load comprises a lumped resistor-inductor-capacitor (RLC) circuit.

15. The system of claim 14, wherein the lumped RLC circuit comprises a plurality of segments, wherein each of the segments comprises:
a respective inductor; and
a respective switch coupled between the respective inductor and the replica driver.

16. The system of claim 15, wherein the inductor of each of the segments has a different inductance.

17. The system of claim 16, wherein the inductance of the inductor of each of the segments is fixed.

18. The system of claim 15, wherein each of the segments further comprises:
a respective resistor coupled between a first end of the respective inductor and a ground;
a first capacitor coupled between the first end of the respective inductor and the ground; and
a second capacitor coupled between a second end of the respective inductor and the ground.

19. The system of claim 12, further comprising an interface controller configured to:
enable the first signal driver, the replica driver, and the receiver in a bidirectional mode; and
disable the replica driver in a unidirectional mode.

20. The system of claim 12, wherein the first chip further comprises a baseband modem configured to:
generate a first baseband signal; and
output the first baseband signal to the first signal driver, wherein the first signal transmitted by the first signal driver comprises the first baseband signal.

21. The system of claim 20, wherein the second chip further comprises an RF receiver configured to:
receive a radio frequency (RF) signal via one or more antennas;
frequency down-convert the received RF signal into a second baseband signal; and
output the second baseband signal to the second signal driver, wherein the second signal transmitted by the second signal driver comprises the second baseband signal.
